(19) United States
(12) Patent Application Publication
(10) Pub. No.: US 2012/0153297 A1
(43) Pub. Date: Jun. 21, 2012

(54) OHMIC CATHODE ELECTRODE ON THE BACKSIDE OF NONPOLAR M-PLANE (1-100) AND SEMIPOLAR (20-21) BULK GALLIUM NITRIDE SUBSTRATES

(75) Inventors: Chia-Lin Hsiung, Fremont, CA (US); You-Da Lin, Goleta, CA (US); Hiroaki Ohta, Tokyo (JP); Steven P. DenBaars, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/195,718

(22) Filed: Aug. 1, 2011

Related U.S. Application Data
(60) Provisional application No. 61/369,559, filed on Jul. 30, 2010.

(51) Int. Cl. H01L 29/20; H01L 21/28

(52) U.S. Cl. 257/76; 438/604; 257/E29.089; 257/E21.158

(57) ABSTRACT

Ohmic cathode electrodes are formed on the backside of nonpolar m-plane (1-100) and semipolar (20-21) bulk gallium nitride (GaN) substrates. The GaN substrates are thinned using a mechanical polishing process. For m-plane GaN, after the thinning process, dry etching is performed, followed by metal deposition, resulting in ohmic I-V characteristics for the contact. For (20-21) GaN, after the thinning process, dry etching is performed, followed by metal deposition, followed by annealing, resulting in ohmic I-V characteristics for the contact as well.

### CROSS-REFERENCE TO RELATED APPLICATIONS

This application claims priority under 35 U.S.C. §119(e) to co-pending and commonly-assigned U.S. Provisional Patent Application Ser. No. 61/369,559, filed on Jul. 30, 2010, by Chia-Lin Hsiung, You-Da Lin, Hiroaki Ohta, Steven P. DenBaars, and Shuji Nakamura, and entitled “OHMIC CATHODE ELECTRODE ON THE BACKSIDE OF M-PLANE AND (20-21) BULK GaN SUBSTRATES,” attorney's docket number 30794.389-US-P1 (2011-026-1), which application is incorporated by reference herein.

### BACKGROUND OF THE INVENTION

1. Field of the Invention

The invention is related to the field of optoelectronic devices such as laser diodes (LDs), and more particularly, to improved ohmic cathode electrodes formed on the backside of nonpolar m-plane (1-100) and semipolar (20-21) bulk gallium nitride (GaN) substrates for optical device applications.

2. Description of the Related Art

To improve the performance of optical devices, electrode technologies for both p-type and n-type electrodes are important.

Reference [1] cited below is a study regarding ohmic backside contacts to m-plane n-type gallium nitride (GaN). In this study, fine polishing and dry etching, followed by thermal annealing at 700° C. for 5 minutes, can contribute to ohmic contact.

However, such fine polishing is different from a thinning process that uses mechanical polishing or chemical mechanical polishing (CMP), as described herein. Instead, fine polishing is performed using 3 mm and 1 mm diamond on a rotating plate.

Thus, there is a need in the art for improved electrode technologies for both p-type and n-type electrodes.

### SUMMARY OF THE INVENTION

The present invention discloses improved ohmic cathode electrodes formed on the backside of nonpolar m-plane (1-100) and semipolar (20-21) bulk GaN substrates for optical device applications. The GaN substrates are thinned using a mechanical polishing process, such as used for cleaved-facet LDs. However, the thinning process induces defects on the surface, resulting in an increase in the specific contact resistivity. For m-plane GaN, after the thinning process, dry etching is performed, followed by metal deposition for the contact, resulting in ohmic I-V characteristics for the contact. For (20-21) GaN, after the thinning process, dry etching is performed, followed by metal deposition for the contact, followed by annealing, resulting in ohmic I-V characteristics for the contact as well.

### BRIEF DESCRIPTION OF THE DRAWINGS

Referring now to the drawings in which like reference numbers represent corresponding parts throughout:

FIG. 1(a) is a plot of I-V (current-voltage) curves of samples A through D, FIG. 1(b) is a plot of I-V curves of samples E through H, and FIG. 1(c) is a plot of I-V curves of sample I.

FIGS. 2(a)-2(d) are scanning electron microscope (SEM) images of top and bird's-eye views of nonpolar m-plane (1-100) GaN samples, wherein FIG. 2(a) comprises two top view images of sample A at 0.1 μm and 25 μm, and one bird's-eye view image of sample A at 20 μm; FIG. 2(b) comprises two top view images of sample B at 0.1 μm and 25 μm, and one bird's-eye view image of sample B at 20 μm; FIG. 2(c) comprises two top view images of sample C at 0.1 μm and 25 μm, and one bird's-eye view image of sample C at 20 μm; and FIG. 2(d) comprises two top view images of sample D at 0.1 μm and 25 μm, and one bird's-eye view image of sample D at 20 μm.

FIGS. 3(a)-3(d) are scanning electron microscope (SEM) images of top and bird's-eye views of semipolar (20-21) GaN samples, wherein FIG. 3(a) comprises two top view images of sample E at 0.1 μm and 25 μm, and one bird's-eye view image of sample E at 20 μm; FIG. 3(b) comprises two top view images of sample F at 0.1 μm and 25 μm, and one bird's-eye view image of sample F at 20 μm; FIG. 3(c) comprises two top view images of sample G at 0.1 μm and 25 μm, and one bird's-eye view image of sample G at 20 μm; and FIG. 3(d) comprises two top view images of sample H at 0.1 μm and 25 μm, and one bird's-eye view image of sample H at 20 μm.

FIG. 4 is a flowchart illustrating the process steps used in one possible embodiment of the present invention.

FIGS. 5(a)-5(d) is a series of schematics further illustrating the process steps used in the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes an ohmic cathode electrode or contact fabricated on the backside of nonpolar m-plane (1-100) and semipolar (20-21) bulk GaN substrates for optical device applications. Ohmic contacts can lower the operational voltage of devices, and cathode contacts on the backside of bulk GaN substrates minimize series resistances. In the present invention, the ohmic cathode electrodes are fabricated after the thinning of the device via mechanical grinding or polishing, which is followed by dry etching, Al (for m-plane) or Ti/Al (for (20-21)) metal deposition, and annealing (for (20-21)).

Nonpolar m-plane (1-100) GaN is a polarization-free material, which has a higher internal quantum efficiency as compared to polar c-plane (0001) GaN. For m-plane GaN, a thinning process is performed, such as required to fabricate cleaved-facet LDs, but the thinning process induces defects on the surface. Dry etching can remove the defects or expose another GaN crystal plane to contribute to ohmic contact. The metal contact, which is comprised of Al, has a low work function, which can form a lower Schottky barrier height with n-GaN.

Semipolar (20-21) GaN has less polarization as compared to c-plane GaN, and is a popular material for fabrication of true green LDs. Like the m-plane GaN, a thinning process is performed, such as required to fabricate cleaved-facet LDs, but the thinning process induces defects on the surface. Dry etching can remove the defects or expose another GaN crystal plane to contribute to ohmic contact. The metal contact, which is comprised of Ti/Al, has a low work function Annealing can make the interface between the metal contacts and GaN highly doped, and increase the possibility of tunneling, as described in Reference [1] cited below.

In both instances, the thinning process can be performed by mechanical polishing or chemical mechanical polishing. The thinning process can destroy the contact, because it induces defects on surfaces. However, it may be necessary for fabricating optical devices, such as cleaved-facet LDs.

Dry etching, which includes inductively coupled plasma (ICP) etching or reactive ion etching (RIE), can remove the defects created by the thinning process. In addition, it can also create micropillars that may enable ohmic contact.

A roughened surface can be created by any number of different treatments, such as thinning, polishing, etching, etc. These treatments that create the rough surface, however, may contain defects that destroy the contact.

Aluminum and titanium are used for the metal contact on the m-plane and semipolar GaN, wherein Al is deposited for m-plane GaN and Ti/Al is deposited for (20-21) GaN. However, other metals with a low work function may work as well. Specifically, a metal contact with a low work function can be used to build a low Schottky barrier height that increases the thermal emission rate and decreases the specific contact resistivity.

Annealing can be performed by rapid thermal annealing (RTA) or laser annealing. Any annealing that can form nitrogen vacancies can benefit ohmic contacts.

Experimental Data

Table I below describes the experimental data provided by the inventors for samples A, B, C, D, E, F, G, H, and I, wherein the table identifies, by sample, the plane being processed, the type of treatment applied, and the thickness of the sample.

TABLE I
The information of planes, treatments, and thickness
from samples A through I

| Sample | | | Thickness |
|---|---|---|---|
| Name | Plane | Treatment | (μm) |
| A | m-plane | No treatment | 325 |
| B | m-plane | Thinning | 225 |
| C | m-plane | ICP exposure | 315 |
| D | m-plane | Thinning and ICP exposure | 215 |
| E | (20-21)-plane | No treatment | 305 |
| F | (20-21)-plane | Thinning | 205 |
| G | (20-21)-plane | ICP exposure | 295 |
| H | (20-21)-plane | Thinning and ICP exposure | 195 |
| I | (20-21)-plane | Thermal annealing after | 195 |
| | | thinning and ICP | |

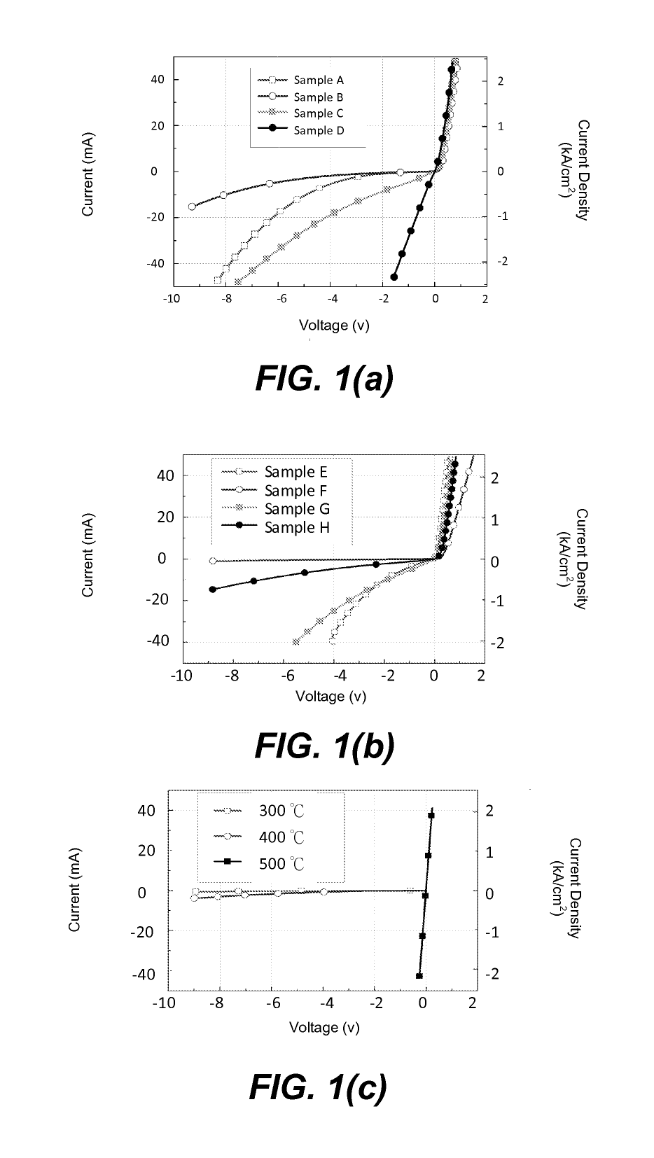

The current-voltage characteristics (I-V characteristics) of the samples are shown in FIGS. 1(a), 1(b) and 1(c), wherein FIG. 1(a) is a plot of I-V (current-voltage) curves of sample A through D, FIG. 1(b) is a plot of I-V curves of sample E through H, and FIG. 1(c) is a plot of I-V curves of sample I. These figures show that sample D, which is an m-plane sample treated with thinning and ICP exposure, can contribute to ohmic contact. It also shows that sample I, which is a (20-21) sample treated with thinning, ICP exposure, and annealing, can realize ohmic contact.

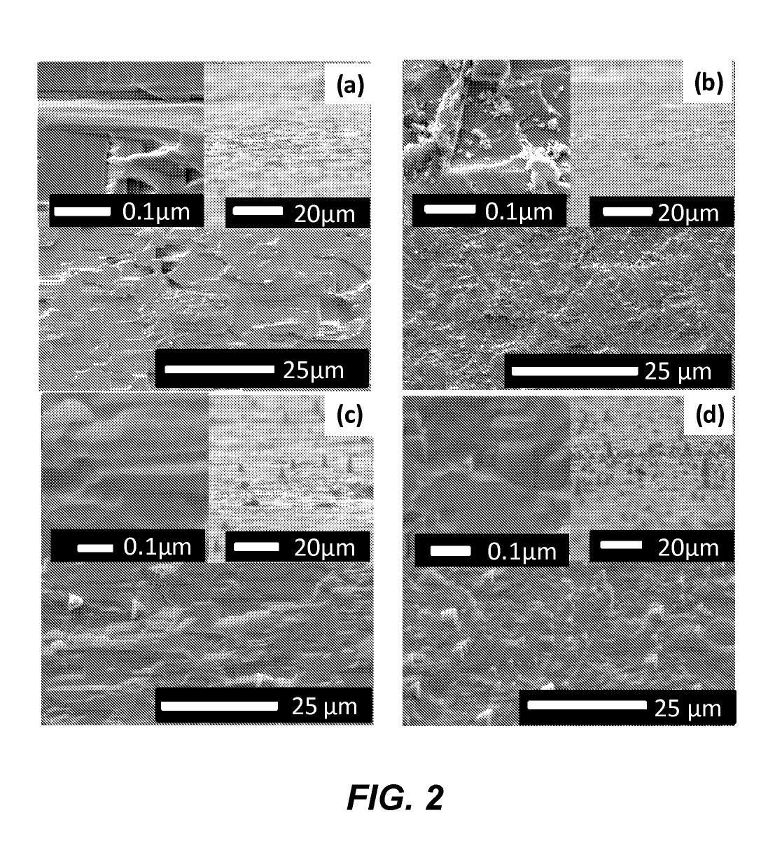

FIGS. 2(a)-2(d) are scanning electron microscope (SEM) images of top and bird's-eye views of m-plane samples, wherein FIG. 2(a) comprises two top view images of sample A at 0.1 μm and 25 μm, and one bird's-eye view image of sample A at 20 μm; FIG. 2(b) comprises two top view images of sample B at 0.1 μm and 25 μm, and one bird's-eye view image of sample B at 20 μm; FIG. 2(c) comprises two top view images of sample C at 0.1 μm and 25 μm, and one bird's-eye view image of sample C at 20 μm; and FIG. 2(d) comprises two top view images of sample D at 0.1 μm and 25 μm, and one bird's-eye view image of sample D at 20 μm. Note that FIG. 2(a) is the sample (A) without any treatment, and FIG. 2(d) is the sample (D) after thinning and dry etching. Many micropillars can be observed in sample D, and FIG. 2(d) clearly shows that, after thinning and ICP exposure, the micropillars in the surface contribute to the ohmic contact.

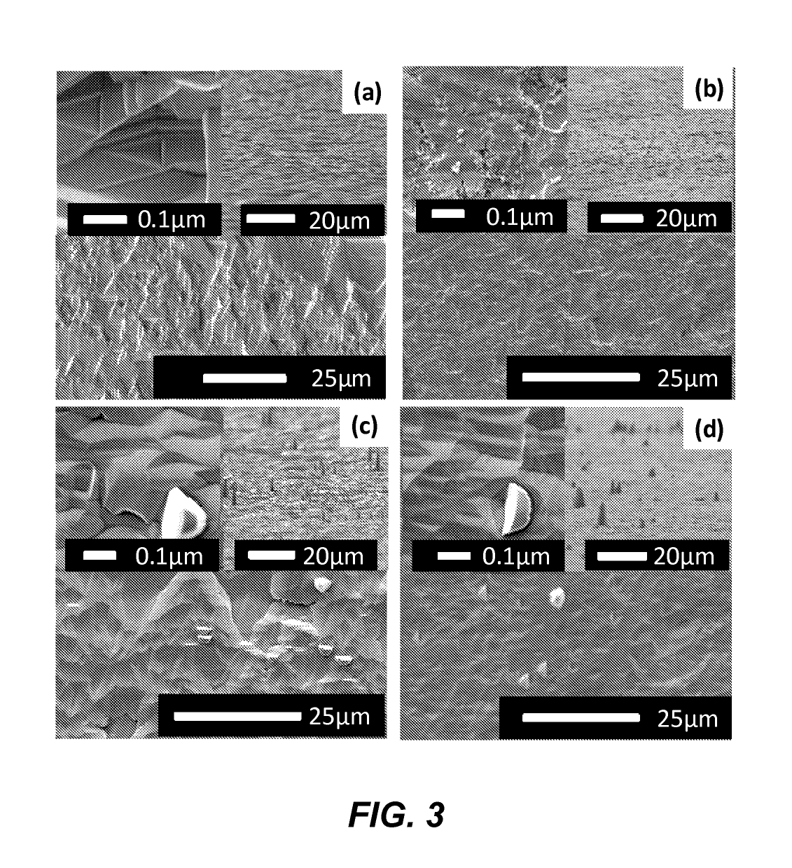

FIGS. 3(a)-3(d) are scanning electron microscope (SEM) images of top and bird's-eye views of (20-21) samples, wherein FIG. 3(a) comprises two top view images of sample E at 0.1 μm and 25 μm, and one bird's-eye view image of sample E at 20 μm; FIG. 3(b) comprises two top view images of sample F at 0.1 μm and 25 μm, and one bird's-eye view image of sample F at 20 μm; FIG. 3(c) comprises two top view images of sample G at 0.1 μm and 25 μm, and one bird's-eye view image of sample G at 20 μm; and FIG. 3(d) comprises two top view images of sample H at 0.1 μm and 25 μm, and one bird's-eye view image of sample H at 20 μm. Note that FIG. 3(d) shows that the density of micropillars in sample H is not as high as in sample D. Therefore, additional annealing is required to achieve ohmic contact for (20-21) GaN.

Process Steps

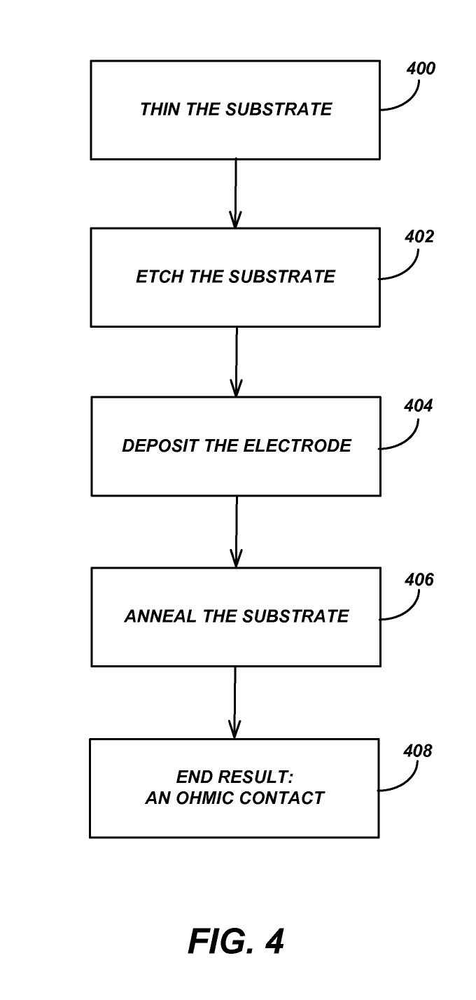

FIG. 4 is a flowchart illustrating the process steps used in the present invention for fabricating an ohmic contact on a backside of a nonpolar or semipolar bulk GaN substrate. In alternative embodiments, the nonpolar bulk GaN substrate is m-plane (1-100) GaN, and the semipolar bulk GaN substrate is (20-21) GaN.

Block 400 represents the step of thinning the substrate via mechanical grinding or polishing. The mechanical polishing may comprise chemical mechanical polishing.

Block 402 represents the step of etching the thinned substrate. The etching may comprise a dry etching that includes inductively coupled plasma etching or reactive ion etching. Moreover, the dry etching may create micropillars that enable ohmic contact between the electrode and the substrate.

Block 404 represents the step of depositing metal for the electrode on the etched substrate, wherein the metal includes at least Al or Ti.

Block 406 represents the step of annealing the substrate after the metal is deposited. The annealing step may include rapid thermal annealing (RTA) or laser annealing.

Block 408 represents the end result of the process steps, namely, an ohmic contact on a semiconductor device, comprising an ohmic electrode fabricated on a backside of a thinned and etched nonpolar or semipolar bulk GaN substrate, wherein the nonpolar bulk GaN substrate is m-plane (1-100) GaN, and the semipolar bulk GaN substrate is (20-21) GaN.

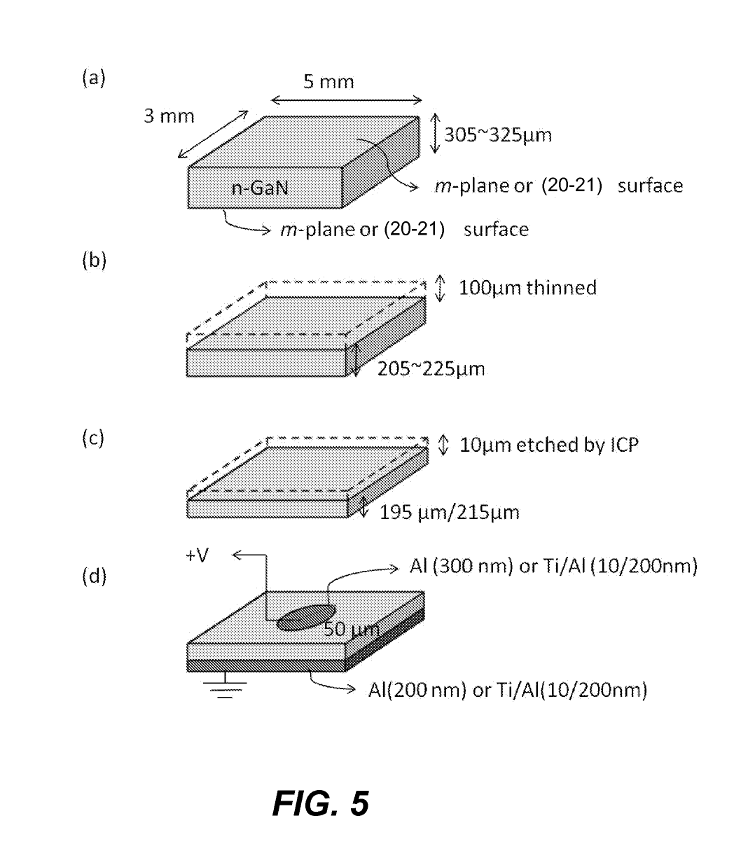

FIGS. 5(a)-5(d) is a series of schematics further illustrating the process steps used in the present invention. FIG. 5(a) shows the as-received sample that measures 5 mm×3 mm×325˜305 μm thick for m-plane and (20-21), respectively; FIG. 5(b) shows the sample after thinning by 100 μm to a thickness of 225˜205 μm for m-plane and (20-21), respectively; FIG. 5(c) shows the sample after thinning and ICP etching by 10 μm to a thickness of 215˜195 μm for m-plane and (20-21), respectively; and FIG. 5(d) shows the sample after contact patterns are formed by standard photolithography for 50 μm inner-diameter circular transmission line measurements (CTLM), followed by metal deposition (i.e., samples D and G), comprising: for one surface, a 300 nm thick Al contact for samples A through H, or a 10 nm/200 nm thick Ti/Al contact for sample I; and, for the other surface, a 200 nm thick Al contact for samples A through H, or a 10 nm/200 nm thick Ti/Al contact for sample I.

Advantages and Improvements

The present invention provides a number of advantages:

1. Achieving ohmic contact on m-plane GaN without annealing, which means that the present invention is both quicker and easier to perform than techniques that perform annealing. Moreover, annealing might adversely affect p-contacts.

2. Achieving ohmic contact on (20-21) GaN with annealing, although the annealing is performed at a temperature under 500° C. for 3 minutes, which is a lower temperature than used in techniques that perform annealing, for example, at 700° C. for 5 minutes for m-plane GaN.

Possible Modifications and Variations

In one embodiment, the present invention is used to fabricate n-contacts on cleaved-facet LDs. However, in alternative embodiments, the present invention can be used with polar/nonpolar/semipolar LDs, polar/nonpolar/semipolar light emitting diodes (LEDs), or any other optical devices that require ohmic contact for good performance. Indeed, the present invention can be used for any contact on a rough surface where ohmic characteristics are desired.

### REFERENCES

The following references are incorporated by reference herein:
[1] Y.-J. Lin, Y.-M. Chen, T.-J. Cheng, and Q. Ker: J. Appl. Phys. 95, 571 (2004).
[2] Chia-Lin Hsiung, You-Da Lin, Hiroaki Ohta, Steven P. DenBaars, and Shuji Nakamura, “Ohmic Cathode Electrode on the Backside of m-plane and (20-21) Bulk GaN Substrates for Optical Device Applications.” This publication is attached as Appendix A to parent U.S. Provisional Application Ser. No. 61/369,559 cross-referenced above.
[3] Y.-A. Chen, D. A. Cohen and S. P. DenBaars, “Low resistance Ti/Al/Au ohmic backside contacts to nonpolar m-plane n-GaN,” Electronics Letters, Vol. 46, No. 2, Jan. 21, 2010. This publication is attached as Appendix B to parent U.S. Provisional Application Ser. No. 61/369,559 cross-referenced above.

### CONCLUSION

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for fabricating a contact on a semiconductor device, comprising:
(a) fabricating an electrode on a backside of a nonpolar or semipolar bulk gallium nitride (GaN) substrate, wherein the fabricating step comprises the steps of:
(1) thinning the substrate via mechanical grinding or polishing;
(2) etching the thinned substrate; and
(3) depositing metal for the electrode on the etched substrate.

2. The method of claim 1, wherein the nonpolar bulk GaN substrate is m-plane (1-100) GaN.

3. The method of claim 1, wherein the semipolar bulk GaN substrate is (20-21) GaN.

4. The method of claim 1, wherein the mechanical polishing includes chemical mechanical polishing (CMP).

5. The method of claim 1, wherein the etching is a dry etching that includes inductively coupled plasma (ICP) etching or reactive ion etching (RIE).

6. The method of claim 5, wherein the dry etching creates micropillars that enable ohmic contact between the electrode and the substrate.

7. The method of claim 1, wherein the metal includes at least Al or Ti.

8. The method of claim 1, wherein the fabricating step further comprises the step of annealing the substrate after the metal is deposited.

9. The method of claim 8, wherein the annealing includes rapid thermal annealing (RTA) or laser annealing.

10. A contact on a semiconductor device, comprising:
(a) an electrode fabricated on a backside of a thinned and etched nonpolar or semipolar bulk gallium nitride (GaN) substrate.

11. The contact of claim 10, wherein the nonpolar bulk GaN substrate is m-plane (1-100) GaN.

12. The contact of claim 10, wherein the semipolar bulk GaN substrate is (20-21) GaN.

13. The contact of claim 10, further comprising micropillars that enable ohmic contact between the electrode and the substrate.

14. The contact of claim 10, wherein the electrode is a metal that includes at least Al or Ti.

15. The contact of claim 10, wherein the substrate is an annealed substrate.
